(19) United States
(12) Patent Application Publication
(10) Pub. No.: US 2022/0137854 A1
(43) Pub. Date: May 5, 2022

(54) RATING MEMORY DEVICES BASED ON PERFORMANCE METRICS FOR VARIOUS TIMING MARGIN PARAMETER SETTINGS

(71) Applicant: MICRON TECHNOLOGY, INC., Boise, ID (US)

(72) Inventors: Murong Lang, San Jose, CA (US); Jian Huang, Union City, CA (US); Zhongguang Xu, San Jose, CA (US); Zhenming Zhou, San Jose, CA (US)

(21) Appl. No.: 17/088,280

(22) Filed: Nov. 3, 2020

(51) Int. Cl. G06F 3/06

(52) U.S. Cl. CPC G06F 3/0653; G06F 3/0625; G06F 3/0679

(57) ABSTRACT

An operation timing condition associated with a memory device to be installed at a memory sub-system is determined. The memory device can include a cross-point array of non-volatile memory cells. The operation timing condition corresponds to a first operation delay timing margin setting for the cross-point array of non-volatile memory cells. A first set of memory access operations is performed at the cross-point array of non-volatile memory cells according to a second operation delay timing margin setting that is lower than the first operation delay timing margin setting. A first number of errors that occurred during performance of the first set of memory access operations is determined. In response to a determination that the first number of errors satisfies an error condition, a first quality rating is assigned for the memory device. In response to a determination that the first number of errors does not satisfy the error criterion, further testing is performed for the cross-point array of non-volatile memory cells based on one or more power level settings.

### TECHNICAL FIELD

Embodiments of the disclosure relate generally to memory sub-systems, and more specifically, relate to rating memory devices based on performance metrics for various time margin parameter settings.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system, in accordance with some embodiments of the present disclosure.

FIG. 2 illustrates an example manufacturing environment, in accordance with some embodiments of the present disclosure.

FIG. 3 is a flow diagram of an example method for rating a memory device based on timing margin performance metrics, in accordance with embodiments of the present disclosure.

FIG. 4 is a flow diagram of another example method for rating a memory device based on timing margin performance metrics.

FIG. 5 is a flow diagram of an example method for rating a set of memory devices based on timing margin performance metrics, in accordance with some embodiments of the present disclosure.

FIG. 6 is a block diagram of an example computer system in which embodiments of the present disclosure may operate.

### DETAILED DESCRIPTION

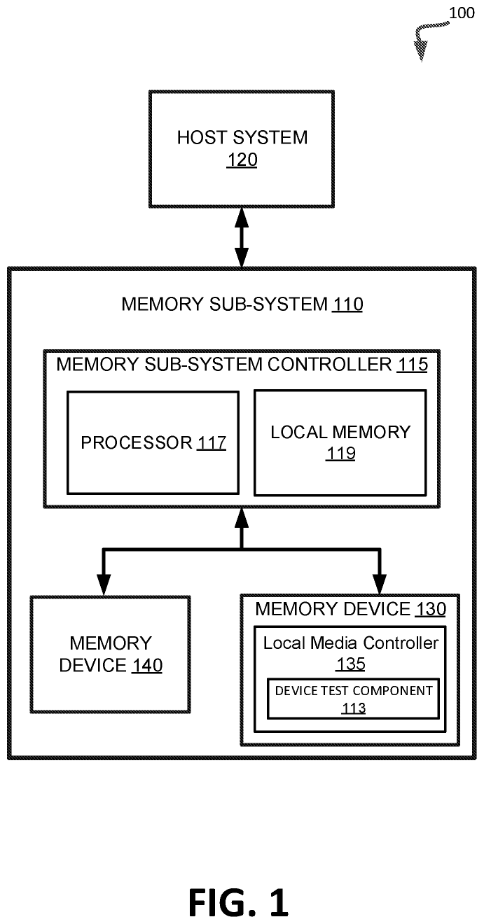

Aspects of the present disclosure are directed to rating memory devices based on performance metrics for various time margin parameter settings. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Another example is a three-dimensional cross-point (“3D cross-point”) memory device that includes an array of non-volatile memory cells. A 3D cross-point memory device can perform bit storage based on a change of bulk resistance, in conjunction with a stackable cross-gridded data access array. Other examples of non-volatile memory devices are described below in conjunction with FIG. 1. A non-volatile memory device is a package of one or more dies. Each die can consist of one or more planes. For some types of non-volatile memory devices (e.g., NAND devices), each plane consists of a set of physical blocks. Each block consists of a set of pages. Each page consists of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional (2D) or three-dimensional (3D) grid. Memory cells are etched onto a silicon wafer in an array of columns (also hereinafter referred to as bitlines (BL)) and rows (also hereinafter referred to as wordlines (WL)). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form a plane of the memory device in order to allow concurrent operations to take place on each plane. A 3D cross-point based memory device (along with its controller) is referred to as a “drive,” which has multiple dies layered in multiple planes known as “decks” in the memory device.

A memory sub-system controller can perform memory access operations (e.g., read operations, write operations, etc.) to access data stored at a memory device by applying a particular voltage for the operation to memory cells storing the data. For certain types of memory devices, a memory access operation (e.g., a read operation) can change the threshold voltage distribution of memory cells, which is referred to as a partial write effect. Over time, the partial write effect induced by a memory access operation can deteriorate threshold voltage distribution of memory cells, and subsequent memory access operations at the same memory cells can have a higher error rate. The threshold voltage distribution can vary after data has been programmed to the memory device. For example, at a particular voltage level, the impact of memory cell corruption can be larger if the memory access operation is performed soon after the data has been programmed as opposed to if the memory access operation is performed at a later time after the data has been written. As the amount of time that has elapsed since the data has been programmed continuously increases, the impact of the corruption can continue to decrease. Thus, the memory cell corruption resulting from a particular memory access voltage can be different between when the data has been programmed and when the data is being read.

A memory sub-system controller can perform memory access operations in view of various operation timing conditions in order to reduce the impact of the partial write effect on memory cells. One example of an operation timing condition is the amount of time after performing an initial memory access operation that elapses before a subsequent memory access operation can be performed. For example, after writing data to memory cells of a memory device, the memory sub-system controller can delay a subsequent read operation at the memory cells until the amount of time associated with the operation timing condition has passed. This type of delay is referred to as an operation-to-operation delay. The amount of time for a delay between particular memory access operations can be optimized to reduce a number of errors caused by memory access operation corruption.

A timing margin in integrated circuits (ICs) corresponds to a difference between the time a signal arrives to a circuit and the latest time the signal can arrive for the circuit to function correctly. The size of a timing margin for a particular memory device can be directly related to the quality of the components of the memory device. For example, the size of a timing margin for a lower quality memory device can be smaller than the size of a timing margin for a higher quality memory device. With respect to the performance of memory access operations, a timing margin corresponds to a period of time after the performance of an initial memory access operation that a voltage can be applied to memory cells for a subsequent memory access operation in accordance with the operation timing condition and a performance condition (e.g., an efficiency condition, a latency condition, etc.) for the memory sub-system. A memory sub-system operates according to various timing margin parameter settings that cause the memory sub-system controller to apply the voltage for a particular memory access operation to memory cells within a timing margin corresponding to that memory access operation. For example, a timing margin for a write-to-read delay can be 100 nanoseconds (ns). A write-to-read delay timing margin parameter can cause the memory sub-system controller to apply the voltage signal for the subsequent read operation to memory cells within the 100 ns timing margin associated with the write-to-read delay.

As described above, the size of a timing margin for a lower quality memory device can be smaller than the size of a timing margin for a higher quality memory device. In accordance with the previous example, a timing margin for a write-to-read delay at a lower quality memory device can be 90 ns instead of 100 ns. This is referred to as a negative timing margin. If a memory sub-system controller is operating according to a timing margin parameter setting that causes the memory sub-system controller to apply the voltage for a subsequent read operation within a 100 ns timing margin, a partial write effect can be induced, which can deteriorate the threshold voltage distribution of the memory cells.

Advanced memory devices, such as 3D cross-point based memory devices, run at an extremely high speed with very precise timing margins. Due to process variations during manufacturing, different dies can have different timing margins, as previously described. Moreover, the signal or power of an assembled memory device can cause the drive voltage level to fluctuate, which can aggravate the variation in timing margin between dies. If the timing margin for a memory device becomes negative and the memory sub-system controller drives the memory device at a high frequency, the memory device cannot operate normally, increasing the error rate associated with the memory device. The memory sub-system controller can perform a significant number of error correction operations to correct defects at the memory device, which causes a performance of the memory sub-system to decrease. In some instances, the negative timing margin can result in a write/read failure beyond the capability of the error correcting code (ECC) to correct the data. In such an instance, the memory sub-system reports the occurrence of an uncorrectable error correcting code (UECC) event.

Aspects of the present disclosure address the above and other deficiencies by rating memory devices based on performance metrics for various timing parameter margin settings. Testing equipment for a manufacturing system can perform a test for each memory device according to various timing margin parameter settings (e.g., operation delay timing margin settings, power level settings, etc.) and rate each memory device based on a performance of the memory device during the test. In some embodiments, the testing equipment can measure the performance of a memory device based on a total number of errors detected after performing a set of memory access operations (e.g., a total number of UECC event reports). In response to determining the number of errors satisfies an error criterion (e.g., exceeds a threshold number of errors), the testing equipment can assign a first quality rating to the memory device. In response to determining that the number of errors does not satisfy the error criterion, the testing equipment can perform additional testing for the memory device and assign a second or a third quality rating to the memory device, based on the outcome of the additional testing.

Advantages of the present disclosure include, but are not limited to, an increase in the overall lifetime of a memory sub-system. By testing memory devices using various timing margin parameter settings, testing equipment can more easily identify memory devices that include manufacturing defects resulting in smaller timing margins. As the smaller timing margins can cause a significant number of errors during the performance of memory access operations at the memory device, the testing equipment can assign an appropriate quality rating to the device. Assembly equipment of the manufacturing system can assemble memory sub-systems in view of the quality rating for each device. For example, assembly equipment of the manufacturing system can use the memory device ratings to assemble a memory sub-system including only memory devices assigned to a high quality rating, which can result in a lower overall error rate for the memory sub-system. A lower overall error rate for a memory sub-system reduces the number of error correction operations performed for the memory sub-system and can decrease the likelihood of unrecoverable data loss. In another example, the assembly equipment can use memory device quality ratings to assemble memory sub-systems that include an equal mix of memory devices assigned a low quality rating and memory devices assigned a high quality rating, which prevents assembly of a memory sub-systems having a significant number of lower rated memory devices. Additionally or alternatively, the testing equipment can identify memory devices having small timing margins that are likely to cause a significant number of errors during operation of a memory sub-system. These identified memory devices can be labeled as defective and the manufacturing system can prevent the assembly equipment from including these memory devices in any memory sub-system.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), and penta-level cells (PLCs) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks. Some types of memory, such as 3D cross-point, can group pages across dice and channels to form management units (MUs).

Although non-volatile memory devices such as 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g., processor 117), configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical MU address, physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

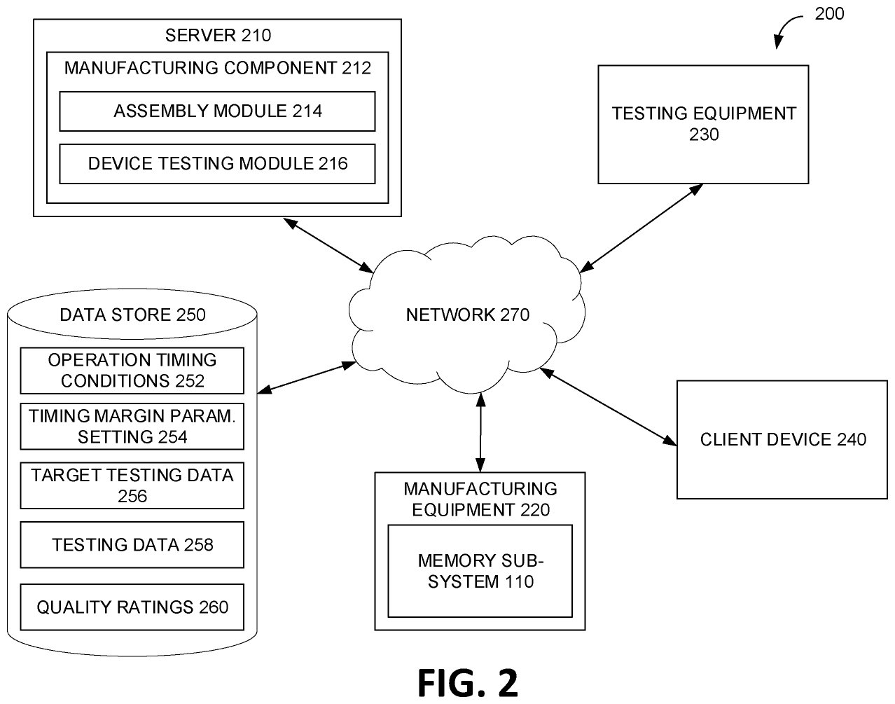

In some instances, one or more tests can be performed for a memory device 130, 140 before the memory device 130, 140 is installed at a memory sub-system 110. For example, before a memory device 130, 140 is installed at a memory sub-system 110, memory device 130 can be tested at testing equipment of a manufacturing system. Memory device 130 can be inserted at the testing equipment. A manufacturing component of the manufacturing environment can perform one or more operations at the memory device inserted at the testing equipment. Local media controller 135 of memory device 130 can include a memory device testing component 113 that can collect testing data associated with the one or more operations performed at the memory device 130. The testing data can include any data used to determine a performance of the memory device (e.g., an endurance, an operation error rate, a latency, a throughput, etc.). For example, the testing data can include a number of errors that occurred during performance of the one or more operations at the memory device, an amount of time between an instance the operation was initiated and an instance the operation was completed, and so forth. Responsive to collecting the testing data, the memory device testing component 113 can transmit the testing data to the manufacturing component. Further details with regards to the operations of the memory device testing component 113 and the manufacturing component are described with respect to FIG. 2 below.

FIG. 2 illustrates an example manufacturing environment 200, in accordance with some embodiments of the present disclosure. Manufacturing environment 200 can include a server 210, manufacturing equipment 220, testing equipment 230, a client device 240, and a data store 250. In some embodiments, each of server 210, manufacturing equipment 220, testing equipment 230, client device 240, and data store 250 can be connected via a network 270.

Server 210 can include a manufacturing component 212 that is configured to facilitate one or more processes at manufacturing environment 200. In some embodiments, manufacturing component 212 can include a memory sub-system assembly module 214 (referred to herein as assembly module 214), a memory device testing module 216 (referred to herein as device testing module 216), and a memory device simulation module 218 (referred to herein as device simulation module 218). Assembly module 214 is configured to facilitate assembly of a memory sub-system, such as memory sub-system 110, at manufacturing equipment 220.

As described with respect to FIG. 1, memory sub-system 110 can include a memory sub-system controller (e.g., memory sub-system controller 115) and one or more memory devices (e.g., memory device 130). In some embodiments, assembly module 214 can select particular memory devices 130 to be installed at a memory sub-system 110 in view of a quality rating 260 for each memory device 130. Manufacturing component 212 can determine a quality rating 260 for each memory device 130 based on a measured performance for each memory device 130. The performance of a memory device can refer to a quality of data stored at the memory device 130 (e.g., a number of errors present in the stored data) and/or an efficiency of an operation performed at the memory device. In some embodiments, manufacturing component 212 can measure a performance of a memory device 130 based on a total number of errors detected after performing a set of memory access operations (e.g., a total number of UECC event reports).

In some embodiments, manufacturing component 212 can measure a performance of a memory device 130 based on testing data, such as testing data 256, collected for the memory device 130 by device testing module 216. Device testing module 216 can facilitate testing of memory device 130 at testing equipment 230. In some embodiments, testing equipment 230 can include a memory device test rack including multiple memory device testing slots. Memory devices 130 can be inserted into respective memory device testing slots and device testing module 216 can execute one or more test operations to be performed at the inserted memory devices.

In some embodiments, device testing module 216 can facilitate testing of a memory device 130 at testing equipment 230 by executing one or more instructions to perform a set of memory access operations (e.g., write operations, read operations, etc.) according to one or more operation timing conditions 252. An operation timing condition 252 refers to an amount of time after performance of an initial memory access operation that a subsequent memory access operation can be performed. An operation timing condition 252 can correspond to the length of a delay between an initial memory access operation and a subsequent memory access operation performed at the memory device, which is referred to as an operation-to-operation delay (e.g., a write-to-write delay, a write-to-read delay, a read-to-read delay, etc.). For example, after writing data to memory cells of a memory device 130, a memory sub-system controller 115 can delay a subsequent read operation at the memory cells until the amount of time associated with the operation timing condition 252 has passed (referred to as a write-to-read delay).

A timing margin corresponds to a margin of time after the performance of an initial memory access operation that a voltage can be applied to memory cells for a subsequent memory access operation in accordance with the operation timing condition 252 and other performance conditions for a memory sub-system 110 (e.g., an efficiency condition, a latency condition, etc.). A memory sub-system 110 including a memory device 130 can operate according to various timing margin parameter settings 254. A timing margin parameter setting 254 refers to a particular setting (e.g., an operation delay timing margin setting, a power level setting, etc.) that causes a processing device to apply the voltage for a particular type of memory access operation within a timing margin corresponding to that type of memory access operation. For example, a write-to-read delay timing margin setting 254 can cause a memory sub-system controller 115 to apply a read operation voltage within a 100 ns timing margin. In another example, a power level setting can cause the processing device to provide a particular level of power to the memory device 130 that maintains the timing margin for memory access operations performed at the memory device 130.

An operation timing condition 252 can correspond to a first set of timing margin parameter settings, which includes one or more timing margin parameter settings 254 that are optimized to reduce the number of errors that occur during the performance of memory access operations. A timing margin parameter setting 254 can include at least one of a write-to-read delay timing margin setting, a write-to-read delay timing margin setting, a read-to-read delay timing margin setting, or a power level setting. In some embodiments, a user of manufacturing system 200, such as an operator, an engineer, a programmer, etc., can provide each of the first set of timing margin parameter settings 254 for memory device 130 (e.g., via client device 240). In other or similar embodiments, device testing module 216 can perform a series of tests for a memory device 130 at testing equipment 230 to determine each of the first set of timing margin parameter settings.

In some embodiments, device testing module 216 can obtain target testing data 256 prior to performing a test for a particular memory device 130. For example, device testing module 216 can perform a set of memory access operations at memory device 130 at testing equipment 230 according to the first set of timing margin parameter settings. The set of memory access operations can include a first series of operations including a write operation and a subsequent write operation for a set of memory cells at a memory device 130, a second series of operations including a write operation and a subsequent read operation for a set of memory cells at memory device 130, or a third series of operations including a read operation and a subsequent read operation for memory cells at memory device 130.

Device testing module 216 can determine a number of errors that occurred during performance of the set of operations according to the first set of timing margin parameter settings. For example, device test component 113 can detect one or more errors resulting from the performance of the set of memory access operations at memory device 130 and can transmit a message to device testing module 216 (e.g., via network 270) indicating the total number of errors that occurred. In some embodiments, the total number of errors can correspond to a total number of UECC events detected at memory device 130 during performance of the set of memory access operations. In some embodiments, device test component 113 might not detect any errors resulting from the performance of the set of memory operations and transmit a message to device testing module 216 indicating that no errors have been detected. In response to receiving the message from device test component 113, device testing module 216 can store the received number of errors, or an indication that no errors were detected, as target testing data 256 at data store. As described previously, each of the first set of timing margin parameter settings are optimized to reduce the number of errors that occur during the performance of memory access operations at a memory device 130. Assembly module 214 can use target testing data 256 as reference data that indicates the number of errors associated with optimized timing margin parameter settings 254 for memory device 130.

In some embodiments, device testing module 216 can obtain target testing data 256 by performing memory access operations for a memory device 130, as described previously. In other or similar embodiments, device testing module 216 might not obtain target testing data 256 by performing memory access operations for a memory device 130 and, instead, can receive target testing data 256 from a user of manufacturing system 200 with the first set of timing margin parameter settings. In other or similar embodiments, device testing module 216 can determine target testing data 256 during the performance of the series of tests to determine each of the first set of timing margin parameter settings, in accordance with previously described embodiments.

Device testing module 216 can test memory device 130 by executing instructions to perform a set of memory access operations at the memory device 130 at testing equipment 230 according to a second set of timing margin parameter settings. It should be noted that device testing module 216 can perform each set of memory access operations described herein on the same memory device 130 or on a different memory device 130. For example, device testing module 216 can perform a first set of operations according to the first set of timing margin parameter settings at a first memory device 130 and a second set of operations according to the second set of timing margin parameter settings at a second memory device 130. The set of operations for the test based on the second set of timing margin parameter settings can include the same operations (or series of operations), or can include different operations, that were included in the set of operations used to obtain the target testing data 256.

The second set of timing margin parameter settings can include at least one setting that is different from the first set of timing margin parameter settings. For example, the second set of timing margin parameter settings can include an operation delay timing parameter setting that causes the a processing device to apply the voltage for a subsequent read operation within a 95 ns timing margin, which is smaller than the timing margin of 100 ns for an operation delay timing margin parameter setting of the first set. In another example, a power level setting of the second set can cause a processing device to provide a smaller level of power to the memory device during performance of the set of memory access operations than a corresponding power level setting of the first set. Device testing module 216 can determine a number of errors that occurred during performance of the set of memory access operations according to the second set of testing margin parameter settings, and can store the received number of errors as testing data 256 at data store 250, as previously described.

In some embodiments, device testing module 216 can perform multiple tests for a memory device 130 according to different sets of testing margin parameter settings. For example, device testing module can perform an additional set of operations at a memory device 130 according to a third set of testing margin parameter settings. The third set of testing margin parameter settings can include at least one timing margin parameter setting that is different from a corresponding parameter setting of the first set and/or the second set of testing margin parameter settings. For example, the third set of testing margin parameter settings can include an operation delay timing margin setting that causes a processing device to apply the voltage for a subsequent read operation within a 90 ns timing margin, which is smaller than the timing margin of 95 ns for the operation delay timing margin setting of the second set and the timing margin of 1000 ns for the operation delay timing margin setting of the first set. In other or similar embodiments, the third set of testing margin parameter settings can include an operation delay timing margin setting that causes the processing device to apply the voltage for a subsequent read operation within a 100 ns timing margin, but can also include a power level setting that causes the processing device to provide a smaller level of power to the memory device than provided during performance of the set of operations according to the first and/or second set of timing margin parameter settings. Device testing module 216 can determine the number of errors that occurred during performance of the additional set of memory access operations and can store the number of errors as testing data 258 at data store 250, in accordance with previously described embodiments.

Assembly module 214 can use testing data 258 to determine a quality rating for a particular memory device 130. For example, assembly module 214 can determine whether a number of errors detected during performance of a set of memory access operations during a test satisfies an error criterion. Assembly module 214 can determine that the number of errors satisfies the error criterion in response to determining the number of errors meets or exceeds a threshold number of errors. In some embodiments, the threshold number of errors can correspond to the number of detected errors of target testing data 256. In an illustrative example, target testing data 256 can include an indication that no errors were detected during a performance of a set of operations according to the first set of timing margin parameter settings at a memory device 130. Testing data 258 can include an indication that device testing component 113 detected one or more errors after the performance of a set of operations according to the second set of timing margin parameter settings. As such, assembly module 214 can determine the number of errors detected during performance of the second set of memory access operations exceeds the threshold number of errors.

In response to determining that the number of errors satisfies the error criterion, assembly module 214 can assign a low quality rating 260 for the memory device 130. In some embodiments, in response to determining the number of errors does not satisfy the error criterion (e.g., the number of errors does not satisfy the threshold value), assembly module can assign a high quality rating 260 for the memory device 130. In some embodiments, the low quality rating 260 can represent a lower quality memory device 130, 140 than a memory device 130 associated with the high quality rating 260. In some embodiments, assembly module 214 can use other testing data 258 collected by device testing module 216 to determine the quality rating 260 for memory device 130. For example, device testing module 216 can perform an additional set of memory access operations according to a third set of timing margin parameter settings at memory device 130, 140, as previously described. In response to determining the number of errors detected for the performance of the additional set of memory access operations satisfies the error criterion, assembly module 214 can assign a medium quality rating 260 to memory device 130. In response to determining the number of errors does not satisfy the error criterion, assembly module 214 can assign the high quality rating 260 to memory device 130, as previously described.

In some embodiments, assembly module 214 can generate and transmit instructions to manufacturing equipment 220 to install particular memory 130 at a memory sub-system 110 based on a quality rating 260 for the memory device 130. For example, assembly module 214 can generate an instruction causing manufacturing equipment 220 install memory devices 130 having a high quality rating 260 at a particular memory sub-system 110. In another example, assembly module 214 can generate an instruction causing manufacturing equipment 220 to install an approximately equal (i.e., 50/50) mix of memory devices 130 having a low quality rating 260 and memory device 130 having a high quality rating 260 at a particular memory sub-system 110. In other or similar embodiments, assembly module 214 can use quality ratings 260 to identify a memory device 130 that is likely defective and is not to be installed at a memory sub-system 110. For example, assembly module 214 can generate an instruction that manufacturing equipment 220 is not to install any memory device 130 having a low quality rating 260 at a memory sub-system 110. In response to generating an instruction regarding the installation of a memory device 130 at a memory sub-system 110, assembly module 214 can transmit the instruction to manufacturing equipment 220. Manufacturing equipment 220 can assembly a memory sub-system 110 including particular memory devices 130, in view of the instruction.

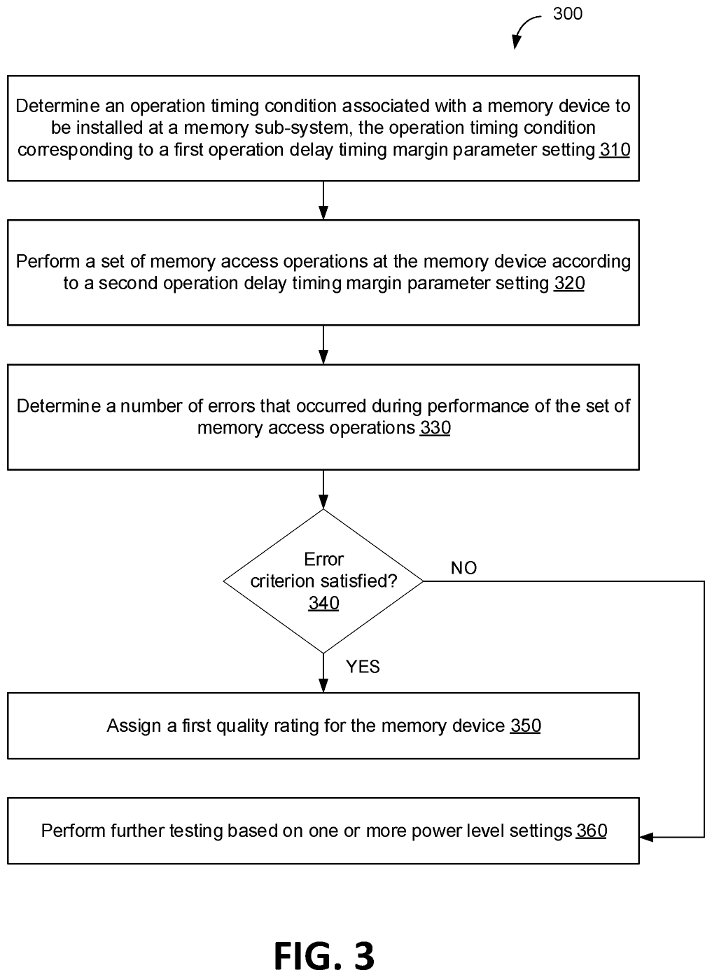

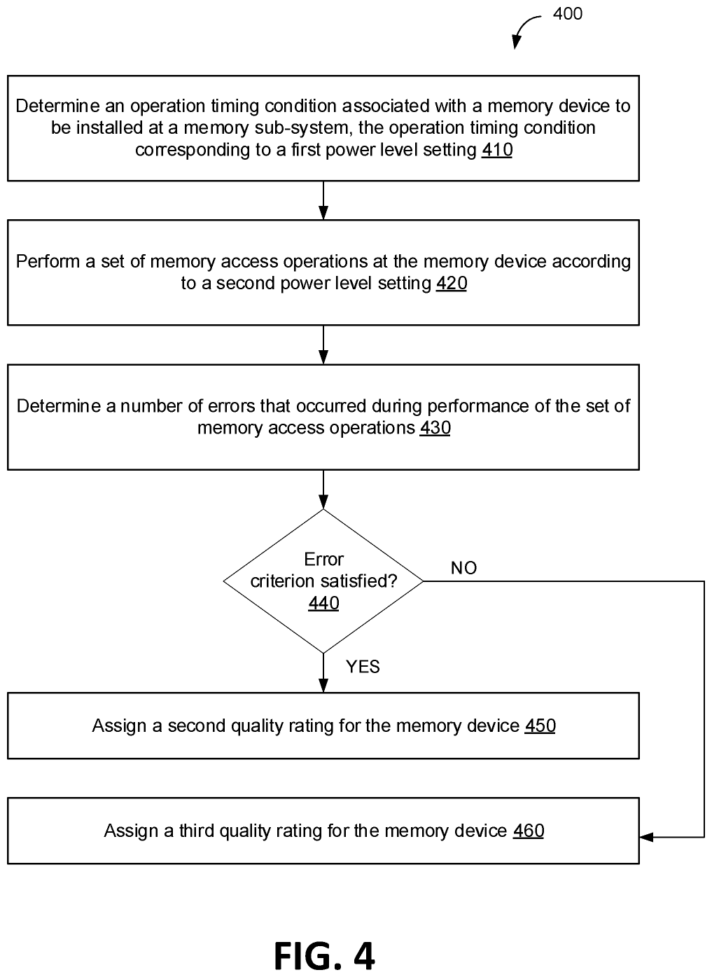

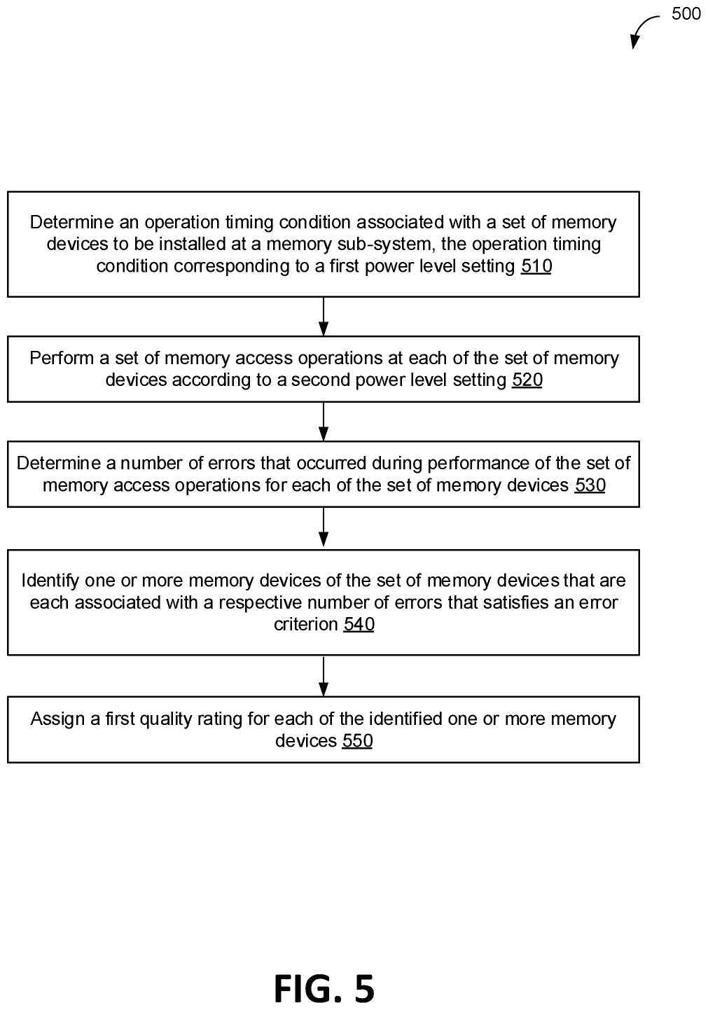

FIGS. 3 and 4 are a flow diagrams of example methods 300, 400 for rating a memory device based on timing margin performance metrics, in accordance with embodiments of the present disclosure. FIG. 5 is a flow diagram of an example method for rating a set of memory devices based on timing margin performance metrics, in accordance with some embodiments of the present disclosure. Methods 300, 400, and/or 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, methods 300, 400, and/or 500 is performed by manufacturing component 212 of FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring now to FIG. 3, at operation 310, the processing logic can determine an operation timing condition associated with a memory device to be installed at a memory subsystem. The memory device can include a cross-point array of non-volatile memory cells. In some embodiments, the operation timing condition can be an operation timing condition 252 described with respect to FIG. 2. The operation timing condition 252 can correspond to a first operation delay timing margin parameter setting that is optimized to reduce a number of errors that occur during a performance of memory access operations at the cross-point array of non-volatile memory cells. At operation 320, the processing logic can perform a set of memory access operations at the cross-point array of non-volatile memory cells according to a second operation delay timing margin parameter setting. In some embodiments, the second operation delay timing margin parameter setting can be lower than the first operation delay timing margin parameter setting, as previously described. In some embodiments, prior to performing the set of memory access operations, the processing logic can modify one or more error correction settings for the memory device to correct an error correction component from correcting errors that occur at the cross-point array of non-volatile memory cells during the performance of the memory access operations. For example, the processing logic can modify an error correction setting to prevent the memory device to execute a redundant disk storage (RAID) error correction operation.

At operation 330, processing logic can determine a number of errors that occurred during performance of the set of memory access operations. For example, device test component 113 of memory device 130 can detect a number of errors that occur during performance of the set of memory access operations and transmit a message to manufacturing component 212 indicating the detected number of errors, as previously described. At operation 340, processing logic can determine whether the number of errors satisfies an error criterion. In some embodiments, processing logic can determine whether number of errors satisfies an error criterion by determining whether the number of errors exceeds a threshold number of errors. In one embodiment, the processing logic can determine that the error criterion is satisfied if the number of errors meets or exceeds the threshold number of errors. If the number of errors does not meet or exceed the threshold number of errors, the processing logic can determine that the error criterion is not satisfied. In response to the processing logic determining that the error criterion is satisfied, method 300 can continue to operation 350, where the processing logic can assign a first quality rating (e.g., a low quality rating) for the memory device. In response to the processing logic determining the error criterion is not satisfied, method 300 can continue to operation 360, where the processing logic can perform further testing of the memory device based on one or more power level settings. Further details regarding testing the memory device based on one or more power level settings are provided with respect to FIG. 4.

FIG. 4 is a flow diagram of another example method 400 for rating a memory device based on timing margin performance metrics. In some embodiments, processing logic can perform one or more operations of method 400 in response to completion of one or more operations of method 300. For example, in response to method 300 continuing to operation 360, processing logic can perform one or more operations of method 400, beginning at operation 410 or at operation 420. In other or similar embodiments, processing logic can perform one or more operations of method 400 without completing one or more operations of method 300. For example, processing logic can perform one or more operations of 400 beginning at operation 410.

At operation 410, the processing logic can determine an operation timing condition associated with a memory device, in accordance with previously described embodiments. The memory device can include a cross-point array of non-volatile memory cells, as previously described. In some embodiments, the operation timing condition can correspond to a power level setting for a cross-point array of non-volatile memory cells that is associated with a particular timing margin. At operation 420, the processing logic can perform a first set of memory access operations at the cross-point array of non-volatile memory cells of the memory device according to a second power level setting. The power level setting can be associated with a second timing margin that is smaller than the first timing margin. At operation 430, the processing logic can determine a number of errors that occurred during performance of the set of memory access operations, in accordance with previously described embodiments. At operation 440, the processing logic can determine whether a number of errors detected during performance of the set of memory access operations satisfies an error criterion. In one embodiment, the processing logic can determine that the error criterion is satisfied if the number of errors meets or exceeds a threshold number of errors. If the number of errors does not meet or exceed the threshold number of errors, the processing logic can determine that the error criterion is not satisfied.

In some embodiments, in response to the processing logic determining that the error criterion is satisfied, the processing logic can assign a first or second quality rating to the memory device. For example, if processing logic performs the operations of method 400 without performing the operations of method 300 (i.e., without testing the memory device based on a modified operation delay timing margin parameter setting), the processing logic can assign a first quality rating (e.g., a low quality rating) to the memory device in response to determining that the error criterion is satisfied. In such embodiments, the processing logic can subsequently perform one or more operations of method 300 (i.e., to test the memory device based on the modified operation delay timing margin parameter setting), in accordance with embodiments previously described. In other or similar embodiments, method 400 can terminate.

In another example, if processing logic performs the operations of method 400 after performing one or more operations of method 300 (i.e., with testing the memory device based on a modified delay timing margin parameter setting), in response to the processing logic determining the error criterion is satisfied at operation 440, method 400 can continue to operation 450 where processing logic assigns a second quality rating (e.g., a medium quality rating) for the memory device. In response to the processing logic determining the error criterion is not satisfied, method 400 continues to operation 460, where the processing logic assigns a third quality rating (e.g., a high quality rating) to the memory device.

FIG. 5 is a flow diagram of an example method 500 for rating a set of memory devices based on timing margin performance metrics, in accordance with some embodiments of the present disclosure. It should be noted that, although embodiments described with respect to FIG. 5 are directed to testing a memory device based on a modified power level setting, processing logic can perform such operations of method 500 to test a memory device based on a modified operation delay timing margin setting, in accordance with embodiments described herein. At operation 510, the processing logic can determine an operation timing condition associated with a set of memory devices to be installed at one or more memory sub-systems. Each memory device can include a cross-point array of non-volatile memory cells. The operation timing condition can correspond to a first power level setting for the cross-point array of non-volatile memory cells that is associated with a first timing margin. At operation 520, the processing logic can perform a set of memory access operations at each of the set of memory devices according to a second lower level setting, in accordance with previously described embodiments. The second power level setting can be associated with a second timing margin that is smaller than the first timing margin. At operation 530, the processing logic can determine a number of errors that occurred during performance of the set of memory access operations for each of the set of memory devices. At operation 540, the processing logic can identify one or more memory devices of the set of memory devices that are each associated with a respective number of errors that satisfies an error criterion. In some embodiments, the processing logic can determine that a number of errors for a memory device satisfies an error criterion by determining that the number of errors exceeds a threshold number of errors. In other or similar embodiments, the processing logic can determine that the number of errors satisfies the error criterion by determining the number of errors for the particular memory device is larger than a number of errors for another memory device of the set of memory devices. At operation 550, the processing logic can assign a first quality rating for each of the identified one or more memory devices. In some embodiments, the processing logic can identify one or more additional memory devices of the set of memory devices having a respective number of errors that does not satisfy the error criterion. In such embodiments, the processing logic can perform and additional test for each of the additional memory devices (e.g., perform another set of memory access operations according to a third power level setting or a modified operation delay timing margin setting), in accordance with previously described embodiments.

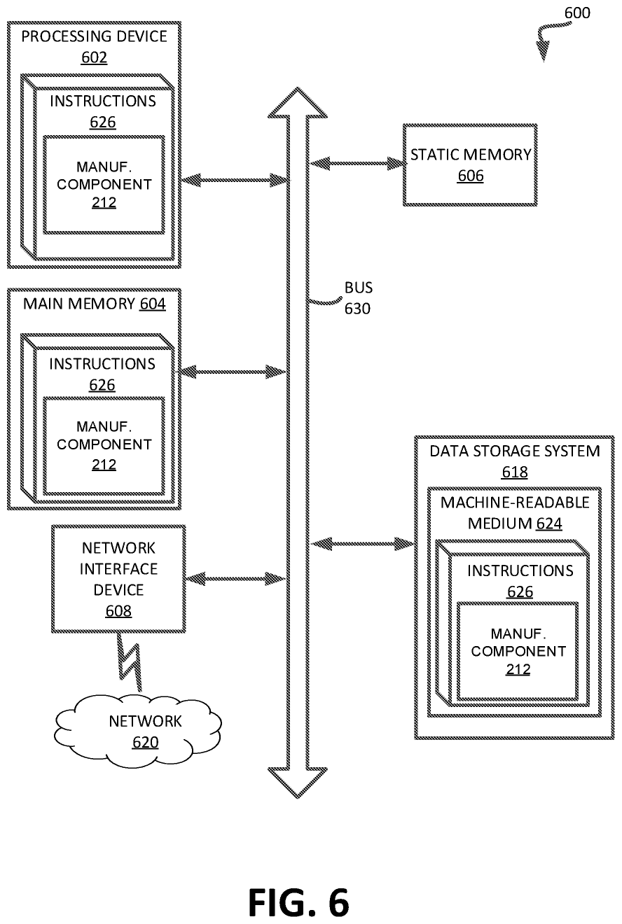

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the device test component 113 of FIG. 1). In other or similar embodiments, the computer system can correspond to a server of a manufacturing system used to perform the operations of a manufacturing component (e.g., manufacturing component 212 of FIG. 2). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or RDRAM, etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1, or server 210 of FIG. 2.

In one embodiment, the instructions 626 include instructions to implement functionality corresponding to a manufacturing component (e.g., the manufacturing component 212 of FIG. 2). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
determining an operation timing condition associated with a memory device to be installed at a memory sub-system, the memory device comprising a cross-point array of non-volatile memory cells, wherein the operation timing condition corresponds to a first operation delay timing margin setting for the cross-point array of non-volatile memory cells;
performing a first set of memory access operations at the cross-point array of non-volatile memory cells according to a second operation delay timing margin setting, wherein the second operation delay timing margin setting is lower than the first operation delay timing margin setting;
determining a first number of errors that occurred during performance of the first set of memory access operations;
responsive to determining that the first number of errors satisfies an error criterion, assigning a first quality rating for the memory device; and
responsive to determining that the first number of errors does not satisfy the error criterion, performing further testing for the cross-point array of non-volatile memory cells based on one or more power level settings.

2. The method of claim 1, wherein the first operation delay timing margin setting and the second operation delay timing margin setting include at least one of a write-to-write operation delay timing margin setting, a write-to-read operation delay timing margin setting, or a read-to-read operation delay timing margin setting.

3. The method of claim 1, wherein determining the first number of errors that occurred during performance of the first set of memory access operations comprises:
receiving one or more uncorrectable error reports during performance of the first set of memory access operations; and
calculating a number of the one or more received uncorrectable error reports.

4. The method of claim 1, wherein the first set of memory access operations comprises at least one of a first series of operations comprising a write operation and a subsequent write operation, a second series of operations comprising another write operation and a subsequent read operation, or a third series of operations comprising a read operation and another subsequent read operation.

5. The method of claim 1, wherein performing further testing for the cross-point array of non-volatile memory cells based on the one or more power level settings comprises:
identifying a first power level setting for the cross-point array of non-volatile memory cells that corresponds to the operation timing condition;
performing a second set of memory access operations at the cross-point array of non-volatile memory cells according to a second power level setting, wherein the second power level setting is lower than the first power level setting;
determining a second number of errors that occurred during performance of the second set of memory access operations; and
responsive to determining that the second number of errors satisfies the error criterion, assigning a second quality rating for the memory device, wherein the first quality rating corresponds to a lower quality memory device than a device associated with the second quality rating.

6. The method of claim 5, further comprising:
prior to performing further testing for the cross-point array of non-volatile memory cells based on the one or more power level settings, performing a third set of memory access operations at the cross-point array of non-volatile memory cells according to a third operation delay timing margin setting, wherein the third operation delay timing margin setting is lower than the second operation delay timing margin setting;
determining a third number of errors that occurred during performance of the third set of memory access operations; and
responsive to determining that the third number of errors satisfies the error criterion, assigning a third quality rating for the memory device, wherein the first quality rating corresponds to a lower quality memory device than a device associated with the third quality rating.

7. The method of claim 1, further comprising:
prior to performing the first set of memory access operations at the cross-point array of non-volatile memory cells, modifying one or more error correction settings for the memory device to prevent an error correction component from correcting errors that occur at the cross-point array of non-volatile memory cells during the performance of the first set of memory access operations.

8. The method of claim 1, wherein determining that the first number of errors satisfies the error criterion comprises:
determining that the first number of errors exceeds a threshold number of errors.

9. A system comprising:
a memory device; and
a processing device coupled to the memory device, the processing device to perform operations comprising:
determining an operation timing condition associated with a set of memory devices each comprising a cross-point array of non-volatile memory cells and to be installed at one or more memory sub-systems, wherein the operation timing condition corresponds to a first power level setting for the cross-point array of non-volatile memory cells that is associated with a first timing margin;
performing a first set of memory access operations at the cross-point array of non-volatile memory cells of each of the set of memory devices according to a second power level setting, wherein the second power level setting is associated with a second timing margin that is smaller than the first timing margin;
determining, for each of the set of memory devices, a number of errors that occurred during performance of the first set of memory access operations;
identifying one or more memory devices of the set of memory devices that are each associated with a respective number of errors that satisfies an error criterion; and
assigning a first quality rating for each of the identified one or more memory devices.

10. The system of claim 9, wherein to determine, for each of the set of memory devices, the number of errors that occurred during performance of the first set of memory access operations, the processing device is to:
receive one or more uncorrectable error reports during performance of the first set of memory access operations at the cross-point array of non-volatile memory cells of a respective memory device; and
calculate, for the respective memory device, a number of the one or more received uncorrectable error reports.

11. The system of claim 9, wherein the first set of memory access operations comprises at least one of a first series of operations comprising a write operation and a subsequent write operation, a second series of operations comprising another write operation and a subsequent read operation, or a third series of operations comprising a read operation and another subsequent read operation.

12. The system of claim 9, wherein the processing device is to perform operations further comprising:
identifying one or more additional memory devices of the set of memory devices that are each associated with a respective number of errors that does not satisfy the error criterion;
performing a second set of memory access operations at the cross-point array of non-volatile memory cells of each of the identified one or more additional memory devices according to a third power level setting for the cross-point array of non-volatile memory cells that is associated with a third timing margin, wherein the third timing margin is smaller than the second timing margin;
determining a second number of errors that occurred during the performance of the second set of memory access operations;
responsive to determining that the second number of errors satisfies the error criterion, assigning at least one of the first quality rating or a second quality rating for each of the identified one or more additional memory devices; and
responsive to determining that the second number of errors does not satisfy the error criterion, assigning a third quality rating for each of the one or more additional memory devices, wherein the third quality rating corresponds to a higher quality device than a device associated with the first quality rating and the second quality rating.

13. The system of claim 9, wherein the processing device is to perform operations further comprising:
identifying a first operation delay timing margin setting for the cross-point array of non-volatile memory cells that corresponds to the operation timing condition;
performing a third set of memory access operations at the cross-point array of non-volatile memory cells of each memory device of the set of memory devices that is associated with a respective number of errors that does not satisfy the error criterion, wherein the third set of memory access operations is performed according to a second operation delay timing margin setting for the cross-point array of non-volatile memory cells that is lower than the first operation delay timing margin setting;
determining a third number of errors that occurred during performance of the third set of memory access operations;
responsive to determining that the third number of errors satisfies the error criterion, assigning at least one of the first quality rating or a second quality rating for each of the identified one or more additional memory devices; and
responsive to determining that the third number of errors does not satisfy the error criterion, assigning a third quality rating for each of the identified one or more additional memory devices, wherein the third quality rating corresponds to a higher quality device than a device associated with the first quality rating and the second quality rating.

14. The system of claim 13, wherein the first operation delay timing margin setting and the second operation delay timing margin setting include at least one of a write-to-write operation delay timing margin setting, a write-to-read operation delay timing margin setting, or a read-to-read operation delay timing margin setting.

15. The system of claim 9, wherein identifying the one or more memory devices comprises:
determining the respective number of errors associated with each of the one or more memory devices exceeds a threshold number.

16. The system of claim 9, wherein identifying the one or more memory devices comprises:
determining the respective number of errors associated with each of the one or more memory devices is larger than the number of errors for each additional memory device of the set of memory devices.

17. A non-transitory computer-readable storage medium comprising instructions that, when executed by a processing device, cause the processing device to perform operations comprising: determining an operation timing condition associated with a memory device to be installed at a memory sub-system, the memory device comprising a cross-point array of non-volatile memory cells, wherein the operation timing condition corresponds to a first operation delay timing margin setting for the cross-point array of non-volatile memory cells;
performing a first set of memory access operations at the cross-point array of non-volatile memory cells according to a second operation delay timing margin setting, wherein the second operation delay timing margin setting is lower than the first operation delay timing margin setting;
determining a first number of errors that occurred during performance of the first set of memory access operations;
responsive to determining that the first number of errors satisfies an error criterion, assigning a first quality rating for the memory device; and
responsive to determining that the first number of errors does not satisfy the error criterion, performing further testing for the cross-point array of non-volatile memory cells based on one or more power level settings.

18. The non-transitory computer-readable storage medium of claim 17, wherein the first operation delay timing margin setting and the second operation delay timing margin setting include at least one of a write-to-write operation delay timing margin setting, a write-to-read operation delay timing margin setting, or a read-to-read operation delay timing margin setting.

19. The non-transitory computer-readable storage medium of claim 17, wherein to determine the first number of errors that occurred during performance of the first set of memory access operations, the processing device is to perform operations comprising:
receiving one or more uncorrectable error reports during performance of the first set of memory access operations; and
calculating a number of the one or more received uncorrectable error reports.

20. The non-transitory computer-readable storage medium of claim 17, wherein the first set of memory access operations comprises at least one of a first series of operations comprising a write operation and a subsequent write operation, a second series of operations comprising another write operation and a subsequent read operation, or a third series of operations comprising a read operation and another subsequent read operation.
